(19) United States
(12) Patent Application Publication
(10) Pub. No.: US 2010/0072368 A1
(43) Pub. Date: Mar. 25, 2010

(54) Spectral Measuring System

(75) Inventors: Urs Boegli, Esslingen (CH); Philipp Bachmann, Forch (CH); Dieter Lubkoll, Berlin (DE)

Correspondence Address: THE WEBB LAW FIRM, P.C., 700 KOPPERS BUILDING, 436 SEVENTH AVENUE, PITTSBURGH, PA, 15219, US

(73) Assignee: MSA AUER GMBH, Berlin (DE)

(21) Appl. No.: 12/525,425

(22) PCT Filed: Jan. 28, 2008
(86) PCT No.: PCT/EP2008/050971

§ 371 Date: Jul. 31, 2009

(30) Foreign Application Priority Data
Feb. 2, 2007 (DE) 10 2007 006 082.5
Nov. 29, 2007 (DE) 10 2007 057 850.6

(51) Int. Cl. H01L 27/14

(52) U.S. Cl. 250/338.4

(57) ABSTRACT

A spectral measuring system for determining substance properties using terahertz radiation comprises: one or more radiation sources of which at least one radiation source is adjustable or configurable with regard to its wavelength, wherein the first radiation source emits first radiation at a predetermined first wavelength; and is characterised by a sensor which responds to further radiation which is based on the radiation of the at least one radiation source; a control unit which is connected to the at least one radiation source and the sensor; wherein the control unit is configured to trigger at least one radiation source and to adjust the wavelength of the at least one adjustable radiation source as well as to read out the sensor.

The invention relates to the generation and detection of coherent waves at frequencies in the terahertz range.

The generation and detection of terahertz wave radiation is of interest for many applications. Terahertz wave radiation can be used particularly in detection systems in security applications in order to locate biological weapon material, explosives, illegal drugs and many other concealed objects. Up till now, the application has been limited by high costs, bulky systems and difficult operation. The invention discloses some new ideas for achieving a terahertz system at moderate costs.

The known terahertz systems operate with ultrashort laser impulses which are rectified in nonlinear crystals or photoswitches and in this way shift their spectrum, which usually lies in the near infrared, to a band having a central frequency of 0 Hz. This is equivalent to a spectrum from almost zero to several terahertz.

In other systems used, a nonlinear optical difference frequency generation is provided, wherein the nonlinear element generates continuous (cw) THz waves at the beat frequency of two lasers.

Some elementary principles on the generation and use of terahertz waves are presented hereinafter.

There is a considerable need for the detection of explosives, biological weapons and new imaging methods in security applications. Some systems in the field of terahertz spectroscopy in some research laboratories have shown promising results. For homeland security, fire fighting, the war against terrorism and defence, this technology is a “must”.

Terahertz radiation corresponds to electromagnetic waves in the frequency range between high-frequency electronics and infrared radiation. This band is designated as “far infrared” and lies in the range of 0.1 to 10 THz (3 mm to 30 μm). Molecules possess absorption bands in this range. It is therefore possible to use this band for spectroscopy. In principle, it is possible to use this radiation in similar ways to that in which IR radiation is used, to detect, identify and measure molecules.

Until a few years ago, this radiation band was hidden in a cloud of measurement problems. Since there was a lack of good and easy-to-handle radiation sources and detectors, the application was limited to highly complex systems in science.

Most of the work hitherto in the field of terahertz radiation uses lasers as coherent radiation sources. This is in contrast to the infrared range where most systems are operated with incoherent thermal radiation sources.

The coherence characterises how well a wave can interfere with itself at a different time. The delay by which the phase or amplitude changes by a significant amount (and therefore the correlation is reduced by a significant amount) is defined as the coherence time TC. The bandwidth of a wave having a long coherence time is very small and vice versa. Coherent waves can interfere with themselves. It is therefore possible to form phase-dependent measuring systems for the optical range, comparable to lock-in amplifiers at the end of the low frequencies.

A laser can only oscillate in a few selected modes which are very coherent. Since many modes are allowed with a fixed phase relationship, it is possible to produce very short radiation pulses.

Whereas picosecond pulses were the standard some years ago, commercial systems extending down to a few femtoseconds are now available. Such short pulses have a very large bandwidth:

1 ps< >1000 GHz=1 THz

10 fs< >100 THz

This is the bandwidth around the base wavelength so that this is typically not terahertz radiation.

Nonlinear optics is the branch of optics which describes the behaviour of light in nonlinear media, i.e. media in which the polarisation P responds nonlinearly to the electric field E of light. This nonlinearity is typically only observed at very high light intensities such as are provided, for example, by pulsed lasers. Various frequency mixing processes are possible, for example:
Second harmonic generation (SHG), generation of light at a doubled frequency (half the wavelength);
Difference frequency generation (DFG), generating light at a frequency which is the difference between the other frequencies;
Optical rectification, generating quasi-static electric fields (a special case of DFG).

The two last-mentioned processes can be used to shift radiation from the easily producible laser light in the visible range into the infrared range. Terahertz time domain spectroscopy (THz-TDS) is carried out by means of a coherent emission and detection system which emits single cycle THz pulses and detects them at high repetition rates. The signal is detected in the form of an electric field and the Fourier transformation of the pulse signal gives both amplitude and phase spectra over a broad spectral range.

Terahertz TDS is compared with the well-established Fourier transformation spectroscopy (FTS) which detects radiation in the form of a power but TDS is advantageous compared with FTS because it yields both phase and amplitude information.

In principle, this is a homodyne system in the frequency range in which the laser wavelengths are shifted from the IR to the THz band and back with the aid of nonlinear elements. Possible nonlinear elements, for example, are Auston switches, semiconductors or inorganic crystals such as KNO or organic crystals such as DAST.

In the time domain, the reference laser pulse is delayed in order to sweep or scan the received radiation strictly synchronously. The resulting curve, as a function of the delay time, can be subjected to a Fourier transformation, for example, a FFT, in order to obtain a spectrum which is the product of the spectrum of the THz source with the transmission curve of the sample to be studied.

With the combination of two laser diodes and a nonlinear element, it is possible to generate a terahertz wave of a single wavelength. The system is comparable to the well-known heterodyne system which is used in any radio.

A method for producing terahertz waves is known, for example, from U.S. Pat. No. 6,144,679. This describes how two radiation sources are directed onto a nonlinear optical element, the wavelengths of the radiation sources being selected in such a manner that a third set of radiation is generated, its frequency lying in the terahertz range. However, in the said documents no reference can be found to a simple determination of substance properties of objects to be studied.

It is therefore the object of the invention to provide a spectral measuring system which allows a rapid and reliable determination of substance properties.

It is furthermore the object of the invention to provide a spectral measuring system which is additionally simple to construct.

According to the invention, the object is achieved with a spectral measuring system configured according to the features of patent claim 1 or the equivalent patent claim 3, 16 or 18. Further features and expedient embodiments of the invention are the subject matter of the dependent claims. The common inventive idea for these solutions is based on the fact that a control unit triggers radiation sources and in coordination with this triggering, reads out a sensor for detecting further radiation based on this radiation. Two possibilities are available for implementation: on the one hand, at least two radiation sources can be provided of which at least one is adjustable with regard to the emitted wavelength. On the other hand, more than two radiation sources can be provided which emit specified wavelengths which differ from one another.

In other words, the common inventive idea of the present solutions is based on the fact that one control unit triggers one or more radiation sources and in coordination with this triggering, reads out a sensor for detecting further radiation based on this radiation. Two possibilities are available according to the invention for implementation: on the one hand, at least two radiation sources can be provided of which at least one is adjustable with regard to the emitted wavelength. On the other hand, more than two radiation sources can be provided which emit specified wavelengths which differ from one another. In addition, in a further approach according to the invention, the idea is pursued to use a single radiation source which is configured to be able to emit several wavelengths to generate terahertz waves or directly emit terahertz waves.

In the case of more than two radiation sources, at least one radiation source which is adjustable with regard to the emitted wavelengths can be provided so that the relevant terahertz frequencies cover a small band.

A measuring device is therefore involved here, which is configured to control an input quantity for an object to be studied and also, in time coordination with this triggering, to detect a corresponding response or output quantity from the object to be studied. This measuring device therefore goes far beyond a purely passive measuring device and also goes far beyond a generating device for pre-determined radiation. Thus, the subject matter according to the invention is designated as “measuring system”.

The term “radiation having a predetermined first wavelength” here designates electromagnetic radiation whose spectrum has a relative maximum at the predetermined wavelength.

By “substance property” reference is made in summary form here to a composition and also to specific properties of an object to be studied. With regard to a composition, a substance property can consist in that the object contains one or more substances. In the field of application of security, the object to be investigated could, for example, be a bag containing one or more explosives. With regard to specific properties, the object to be studied could, for example, be the surface of an open semiconductor chip whose operation is to be monitored. In this case, the substance property would then be a different reflectivity of the semiconductor tracks as a function of different operating states.

According to one principal aspect of the invention, the spectral measuring system according to the invention for determining substance properties using terahertz radiation comprises at least two radiation sources of which at least the first radiation source is adjustable with regard to its wavelength. In this connection, it is naturally also feasible that a plurality of radiation sources are provided, for example, three or more, of which several or even all thereof are adjustable with regard to their wavelength.

The first radiation source emits first radiation having a predetermined adjusted first wavelength and the second radiation source emits second radiation having a predetermined second wavelength which differs from the first wavelength. For the envisaged application purposes, the radiation sources are preferably designed as lasers, for example, Nd-YAG or diode lasers.

The first and second radiation together produce a radiation combination which is brought into an interaction with an object to be studied in cooperation with various optical components. In cooperation with further optical components, further radiation is then formed which is ultimately based on the first and second radiation. The measuring system according to the invention comprises a sensor which responds to this further radiation. This further radiation is converted by the sensor into an electrical signal. The measuring system according to the invention further comprises a control unit. The control unit is configured to trigger the at least two radiation sources and to adjust the wavelength of the at least one adjustable radiation source and to read out the sensor.

According to a preferred embodiment according to the invention, terahertz radiation is formed in a sample space region in which the object to be studied is optionally located as a function of the radiation of the at least two radiation sources. The wavelength of the terahertz radiation depends on the wavelengths of the radiation sources. By varying the wavelength of the adjustable radiation source and reading out the sensor coordinated with the wavelength variation, it is possible for the measuring system according to the invention to record a terahertz spectrum of the object to be studied. Depending on the arrangement of the components with respect to one another, this can comprise an absorption or a reflection spectrum.

In this case, a slight detuning of the adjustable radiation source already effects a large variation in the generated terahertz range. The great advantage of such a system is that many of the elements required are standard components from the field of fibre optics in telecommunications or measurement methods in the near infrared range. In principle, the emitter or even the receiver could be implemented in a single-chip solution or as a multichip module in a semiconductor housing.

In an alternative embodiment, the spectral measuring system for determining substance properties using terahertz radiation comprises more than two radiation sources which emit radiation having specified wavelengths which differ from one another. Arrangements comprising three or four or more lasers having specified wavelengths are feasible here. A control unit in this embodiment is configured to trigger this plurality of radiation sources in such a manner that from this plurality of radiation sources, only precisely two radiation sources are ever switched on and the remainder are switched off. In time coordination with this triggering, the control unit reads out the sensor which responds to further radiation which is based on the combination of the respectively two selected radiation sources. In the case of N radiation sources, N*(N−1)/2 two different radiation combinations are feasible. In this way, similarly to that described above, a terahertz spectrum of an object to be studied can be recorded at N*(N−1)/2 reference points.

The measuring system according to the invention further comprises an input-output unit and a data memory which are both connected to the control unit. At least one terahertz spectrum of a known substance is stored in the data memory. The control unit is configured to compare a terahertz spectrum of an object to be studied recorded as described above with the at least one stored terahertz spectrum and to output the result of the comparison to the input-output unit. In turn, a known terahertz spectrum of an explosive could be stored in the data memory in relation to an application in the security area. After a terahertz spectrum of an object to be studied has been recorded as described above, the control unit compares the currently measured spectrum with the stored spectrum. This comparison is made by means of a method which is known to be used for comparing spectra. For example, a Euclidian distance could be calculated between the measured and the stored spectrum. If a pre-definable threshold value is fallen below, an agreement is then identified, if the threshold value is exceeded, a non-agreement is identified. The result of this determination is then output to the input-output unit. This output can be effected in such a manner that in the event of non-agreement, merely a text with the content “no agreement found” is output on a screen whereas in the event of an agreement, an alarm signal is output, together with the text “Alarm: explosive A identified”. However, a warning message can also be sent to predetermined persons or devices by means of a network connection or a telecommunications connection (e.g. ISDN or GSM module).

A plurality of terahertz spectra of known substances can be stored in the data memory. After the terahertz spectrum of an object to be studied has been recorded, the control unit is then in a position to determine which substance is located in the object to be studied by comparing the stored spectra with the recorded spectrum. For example, terahertz spectra of usual explosives as well as terahertz spectra of usual (harmless) packaging or bag material such as leather, PE, linen etc. can be stored. Thus, a greater security can be achieved in that a necessary alarm is not suppressed. In addition, before assembling and programming the measuring system, it is possible to record terahertz spectra of substance combinations. For example, a series of spectra with 99% explosive A, 1% leather to 10% explosive A, 90% leather can be recorded. If this series of spectra is stored in the data memory, the measuring system according to the invention is in a position to also determine substance compositions. Pre-recorded series of measurements with more than two constituents are also possible. In this way, the reliability of the measuring system is increased. This can be of crucial importance for security applications. A particular advantage with this measuring system is that largely untrained operating staff can also use this. Thus, this system can easily be used, for example, in air ports where a high throughput of examinations is usually required.

In the measuring system according to the invention, the beam paths of the radiation sources are directed onto a reference beam splitter in such a manner that one partial beam is incident on a first optical element and a second partial beam is directed onto a deflecting system.

A radiation field can then be emitted by the first optical element which can comprise further wavelengths in addition to the emitted wavelengths.

A second optical element is disposed in relation to the first optical element and the deflecting system in such a manner that it can absorb at least some of the radiation of the radiation field. For example, in one embodiment the first optical element, the second optical element and the sample space region containing the sample can be disposed successively in a row. Then, the sample would be transilluminated, as it were, the measurements would therefore be made in transmitted light. This is possible when liquid or gaseous media are to be studied. Alternatively, the optical elements could be disposed in relation to the sample in such a manner that the measurement is made in reflected light. This is advantageous, for example, when the activity of a semiconductor chip is to be observed.

Preferably radiation is emitted by the second optical element which can be detected by the sensor.

In a preferred embodiment, the radiation sources are configured as lasers and the first and second optical element are configured as nonlinear optical elements.

For example, the radiation sources are configured as diode lasers. Diode lasers have the particular advantage that they are small and available relatively cheaply.

The radiation combination of the radiation sources and the first nonlinear optical element particularly advantageously cooperate in such a manner that the radiation field is radiation in the terahertz range from 0.1 terahertz to 100 terahertz. This frequency range is particularly well suited for irradiating opaque samples. Whereas x-ray radiation is too dangerous and conventional infrared radiation and visible light are too weak, terahertz radiation presents a practical possibility for transilluminating samples safely and securely.

The deflecting system can be implemented by mirrors, alternatively however, it is also considered to use light-guiding fibres. The unperturbed radiation combination from the radiation sources, i.e. that uninfluenced by the nonlinear optical element, is directed by means of the deflecting system as reference radiation onto the second nonlinear optical element. In the nonlinear optical element, the terahertz radiation and the reference radiation then interact in such a manner that readily detectable radiation is again produced.

In a particularly preferred embodiment of the measuring system according to the invention, the radiation sources are integrated with a radiation amplifier on a semiconductor chip. This allows a particularly compact design. In addition, the manufacture and alignment during assembly of the measuring system according to the invention are considerably simplified.

The measuring system allows at least one of the radiation sources to be sinusoidally or rectangularly modified. In this way, the deviation of the absorption spectra can also be measured.

Furthermore, in the measuring system the beam paths of the more than two radiation sources are disposed in such a manner that they are directed onto the first optical element so that a plurality of terahertz waves can be produced according to predetermined switching frequencies of the radiation sources.

In the measuring system according to the invention, each radiation source can be connected to a different frequency so that the resulting terahertz waves can be modulated at different frequencies. As a result of the switching sequence produced in this way, for example, firstly the first and second, then the second and third and finally the third and first radiation source can irradiate onto the nonlinear crystal so that three different terahertz waves can be successively produced.

Furthermore, in the measuring system according to the invention, the phase matching in the first optical element is improved by different phase angles of the incident radiation. It is a known problem in nonlinear optics that the new radiation fields generated by the nonlinear effects propagate at different speeds in the nonlinear element compared with the originally irradiated radiation fields. As a result, phase relationships can be formed which lead to undesirable destructive interferences. This problem is solved by so-called phase matching (index-matching, matching the refractive index). A more favourable interference behaviour can be established by suitable use of dispersion and birefringence as well as suitable arrangement of the radiation fields in relation to the axes of the anisotropic nonlinear optical element.

In a further preferred embodiment of the measuring system according to the invention, the radiation of the radiation sources can be coupled onto optical fibres. In this way, deflecting mirrors which must be aligned with some effort so that the radiation is incident in a predetermined manner on the first optical element, are eliminated.

In particular, the radiation from the radiation sources can be coupled onto an individual optical fibre. If only one fibre is present, it is particularly simple to align the emerging radiation field onto the first optical element. This again simplifies the fabrication of the measuring system.

The outlet end of the said fibre can be disposed in relation to the first optical element and the second optical element in such a manner that the radiation emerging from the fibre can be incident partially on the first optical element and partially on the second optical element. This is achieved by providing a beam splitter at the outlet end of the fibre, having one radiation outlet surface facing the first optical element and the other radiation outlet surface facing the second optical element.

In a further embodiment of the measuring system according to the invention, imaging optical elements are provided. These can be, for example, lenses fabricated from polyethylene. The lenses can furthermore be designed as Fresnel lenses.

At least one of the optical elements is designed as a nonlinear optical element consisting of DAST (dimethyl amino 4-N-methylstilbazolium tosylate), KDP, ADP, lithium niobate, Ba2NaNb5O15, quartz, GaAs, GaP, BaTiO3, ZnO or CdS. This list of possible starting materials is merely to be seen as an example. Other suitable materials can also be considered for use.

In the measuring system according to the invention, the control unit can be designed as an ASIC. If the control unit is designed as an ASIC, easy and inexpensive mass production is possible. Alternatively, the control unit can also be designed as a DSP. A particularly rapid processing of the measurement data is thus possible. In this way, currently measured spectra with a large number of reference points can be rapidly compared with the stored spectra, so that a rapid and very reliable specification of substance properties is possible.

In the measuring system according to the invention, the control unit can alternatively be designed as an embedded system. This is particularly advantageous for measurement setups in the research field. Easier reconfigurability and adaptation to changed measurement task is thus made possible.

According to a further advantageous embodiment, in the measuring system according to the invention the data memory can be configured by an external source. In this way, further data sets in the form of wavelengths, intensities and assigned material data can be supplied dynamically, i.e. even after fabrication and delivery.

In particular, in the measuring system according to the invention, it is possible to configure the data memory by means of a network connection, an internet connection, a telecommunications connection or an inductive connection. Naturally, it can alternatively be considered to simply exchange the memory. A more rapid reconfiguration is naturally possible by means of purely electronic methods. The reconfiguration of the memory can comprise adding further data sets. However, it is naturally also possible to supply an activation code per configuration process by which means the already-stored data sets can be activated or blocked in a predetermined manner for evaluation calculations. In this way, a purchaser of a measuring system according to the invention can gradually extend the measuring system against payment of a fee in such a manner that more and more substances can be displayed or substances which have become uninteresting in the course of research work can be put into the background again.

To sum up, the measuring system according to the invention therefore makes it possible to identify substances or substance properties using the particular features of terahertz radiation. The suitable triggering of a plurality of radiation sources has the result that a time sequence of predetermined terahertz wavelengths is formed in a first nonlinear optical element. In this way, a spectrum is as it were traversed. The measurement of the resulting radiation with the aid of a further nonlinear optical element results in spectral information of the substance or structure to be studied. The control unit then compares this spectral information with spectra of already-known substances or structures which spectra are stored in the data memory. In this way, the control unit can determine which substance/substances/structures are present in the measurement object to be studied. This allows a particularly rapid identification of dangerous substances. Since the measuring system according to the invention can be operated very simply, it is extremely suitable for example, for security in airports or for defence against terrorism.

In other words, the measuring system according to the invention in a particularly preferred embodiment comprises nonlinear elements such as, for example, DAST crystals which are operated by one or more lasers. In particular, it is provided to use a stabilised laser and an adjustable laser for scanning the terahertz spectrum. Alternatively, however, more than two lasers can also be provided. Thus, a predetermined spectral range can be detected quasi-simultaneously. By comparing the measured spectra with spectra stored in a data memory, an indication of the substance under study can be output rapidly and reliably. The detection itself can be effected optically synchronously using a second nonlinear element by homodyne detection. It is particularly advantageous to provide N lasers so that a plurality of frequencies can be generated in the terahertz range. With N lasers it is possible to generate N*(N−1)/2 different terahertz wavelengths. In addition, each terahertz wave can be modulated at individual frequencies if each laser is modulated with pulses according to different repetition rates. The pulse repetition rate of the laser must be selected in such a manner that the beat frequencies between the pulse repetition rates of all the lasers are different. This scheme can be used to detect each of the terahertz waves with phase-sensitive elements such as, for example, lock-in amplifiers at their individual frequencies.

In the event that a plurality of wavelengths are emitted to generate terahertz waves, radiation having at least two predetermined wavelengths which differ from one another are emitted from the radiation source. Predetermined means in this case that it is determined by the dimensions or the triggering which wavelengths are emitted. At the same time, it can also be provided that at least one of the wavelengths is adjustable.

Considered as an example here is a two-colour laser, for example, a two-colour diode laser. In the two-colour diode laser the laser resonator is operated in such a manner that the laser emits two sets of radiation having different wavelengths. The advantage of such a laser is that even during manufacture, it can be fabricated as a module so that no further fine adjustment is required when installing in a measuring system. The emitted wavelengths differ only slightly. The beats produced during the overlap of the coupled-out wavelengths are directed onto an optical element which converts this radiation energy into terahertz waves. The two-colour diode laser can be configured in such a manner that at least one of its wavelengths is adjustable in operation. The two-colour diode laser is based on the fact that two adjoining regions of a semiconductor have a different geometry so that two different laser regions having correspondingly different wavelengths are present in one and the same semiconductor. For varying the wavelength of only one of the laser regions, for example, the resonator mirror is moved for only the one laser region. It is thereby possible to generate two predetermined wavelengths of which at least one wavelength is variable. In the measuring system described, the sensor responds to radiation based on the radiation of the radiation source. For example, the superposition of at least two sets of radiation has the result that a third set of radiation having a wavelength different from the wavelengths of the first at least two sets of radiation is generated. This third radiation is advantageously terahertz radiation.

According to an equivalent aspect, the radiation source itself emits terahertz radiation. This terahertz radiation is emitted by a first element. This element can be designed as an optical element, for example, as a nonlinear optical element or as an electrical element, for example, as a photoconducting antenna. In the case of the photoconducting antenna, a high-intensity light pulse of short duration, possibly 1 ps, is directed onto a photoconducting antenna, to which a voltage is applied. The light pulse generates free charge carriers so that a short current pulse is formed in the electric field. This induces a pulse of an electromagnetic wave in the terahertz wave range. The second element can be an optical or electrical element as in the manner described.

However, it is also possible to generate the terahertz radiation by one or more electronic components. A plurality of frequency doublers can be located after these, in which case several frequencies of the one or the plurality of electronic components can be used.

It is also possible that the radiation source in the measuring system generates a comb of terahertz radiation. The generation of such a terahertz frequency comb is described, for example, in “Terahertz Comb Frequency Generation in Nonlinear Optical Devices”, Proc. of SPIE, Vol. 6373 (2006). Such a choice of radiation source has the advantage that a plurality of frequencies are present simultaneously and the triggering of the radiation source is simplified.

To sum up, the measuring system according to the invention thus makes it possible to identify substances or substance properties, using the particular features of terahertz radiation.

Thus, an inexpensive spectral measuring system for the terahertz range is presented here, the solutions and performance features achieved, risks and costs in relation to the areas of application of biological and chemical weapons, explosives and “looking through the wall” being stressed.

Exemplary embodiments of the spectral measuring system according to the invention are explained in detail with reference to the appended figures. In the figures:

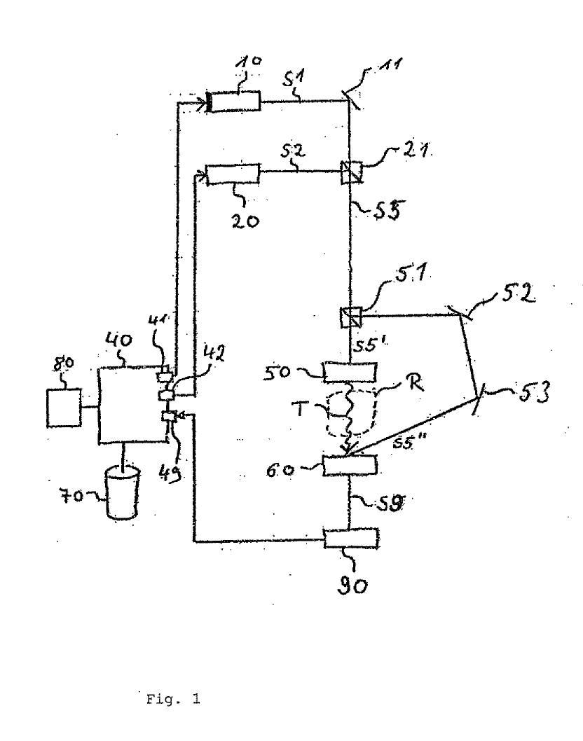

FIG. 1 shows a schematic diagram of the spectral measuring system in a first embodiment;

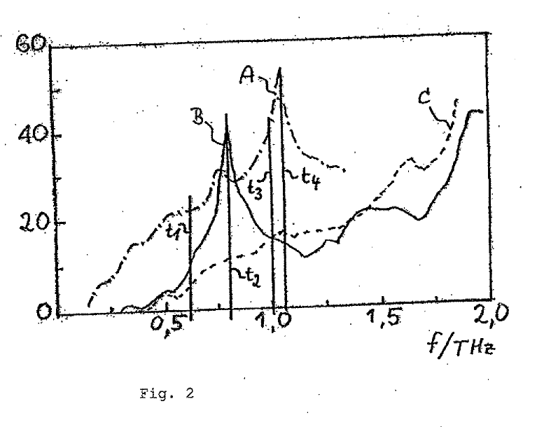

FIG. 2 shows three terahertz spectra of different explosives;

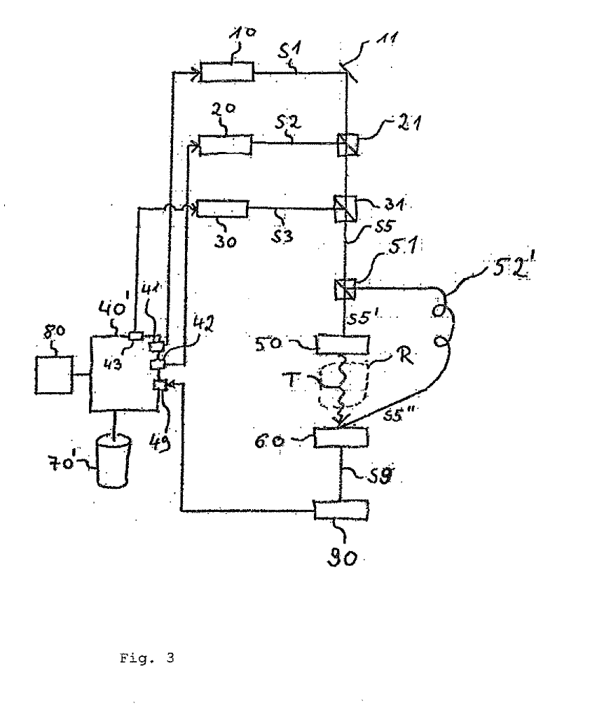

FIG. 3 shows a schematic diagram of the spectral measuring system in a second embodiment;

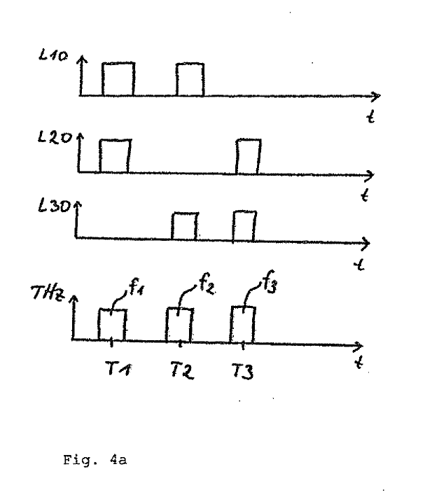

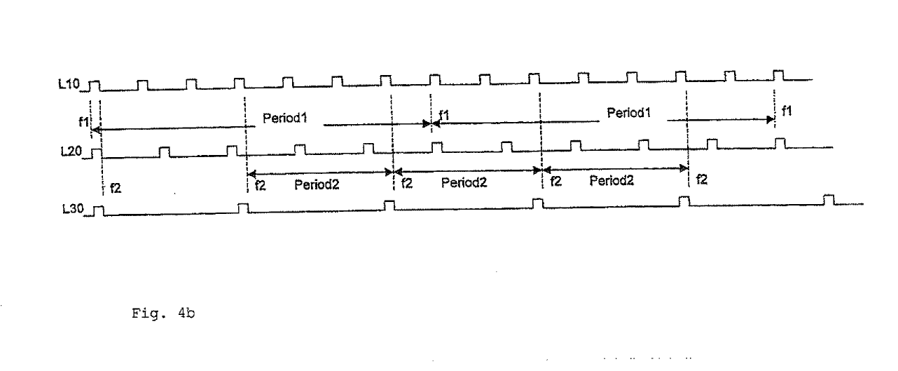

FIG. 4a shows a schematic triggering diagram of the laser in the spectral measuring system in the second embodiment;

FIG. 4b shows an alternative schematic triggering diagram of the laser in the spectral measuring system in the second embodiment;

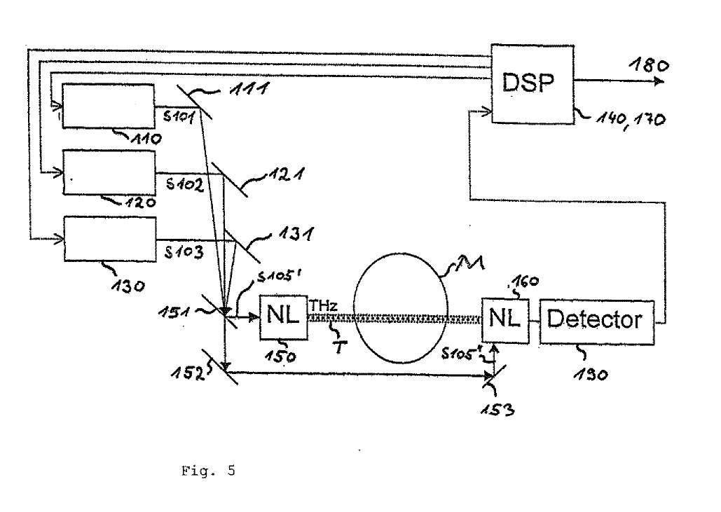

FIG. 5 shows a schematic diagram of the spectral measuring system in a third embodiment;

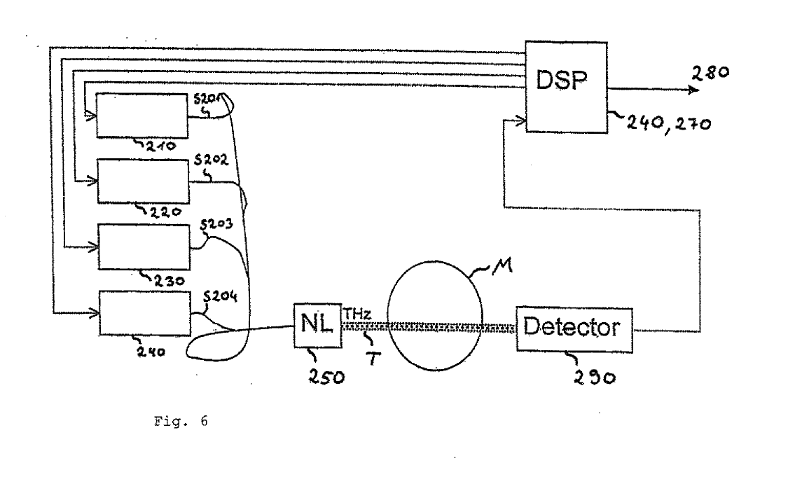

FIG. 6 shows a schematic diagram of the spectral measuring system in a fourth embodiment;

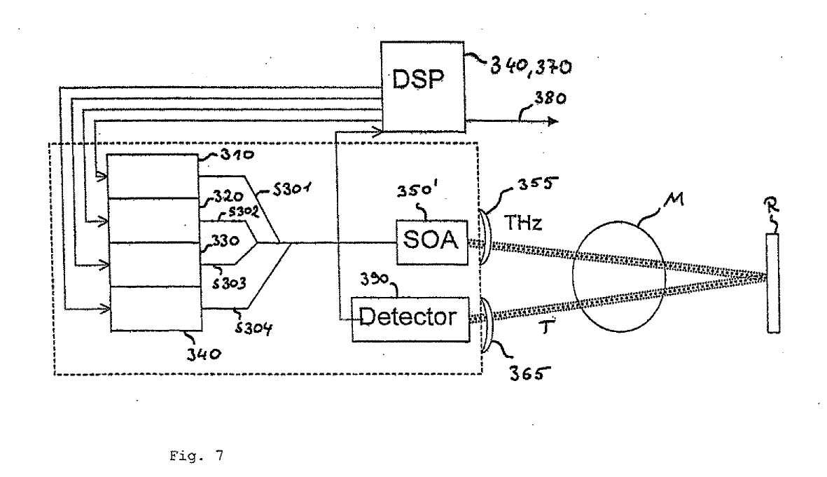

FIG. 7 shows a schematic diagram of the spectral measuring system in a fifth embodiment;

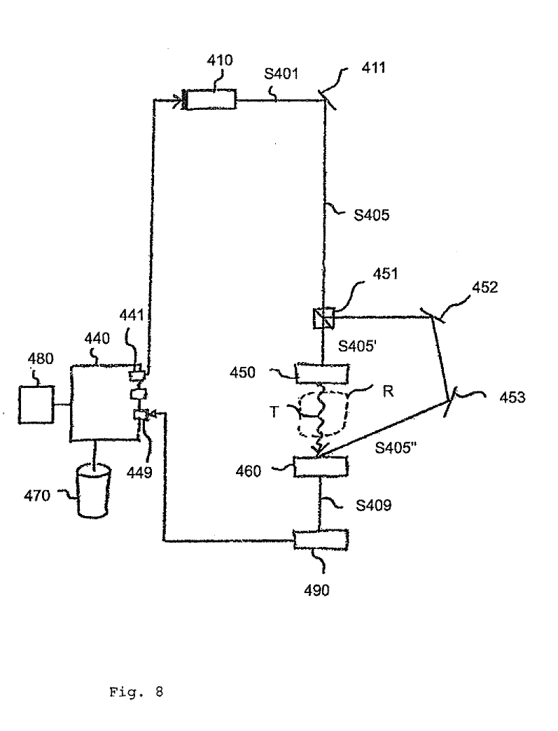

FIG. 8 shows a schematic diagram of the spectral measuring system in a sixth embodiment; and

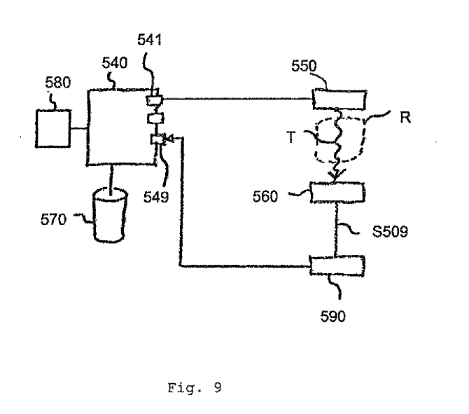

FIG. 9 shows a schematic diagram of the spectral measuring system in a seventh embodiment; and

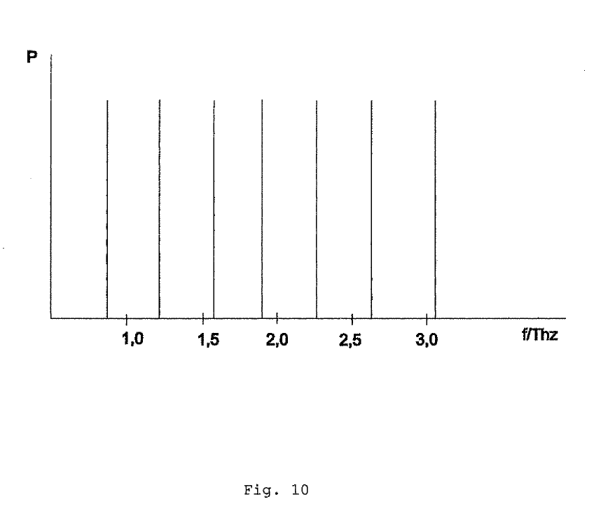

FIG. 10 shows a schematic diagram of a terahertz frequency comb.

FIG. 1 shows the first embodiment of the spectral measuring system according to the invention. In this case, only the elements absolutely necessary to explain the invention are shown in this case. It is clear that further elements can be incorporated in a known manner such as, for example, variable delay sections, λ/2 or λ/4 plates, suitably selected filters and the like. A first laser 10 (first radiation source) and a second laser 20 (second radiation source) are triggered by a control unit 40 via the respective interface 41 and 42. The control unit 40 is configured to switch the lasers 10 and 20 on and off. The control unit 40 is further capable of adjusting the wavelength of at least one of the lasers 10, 20. This is achieved by a suitable adjustment of the temperature and the operating current of the respective laser 10, 20. In the present example it is assumed that the wavelength of the laser 10 is adjusted in a predetermined manner. For example, the laser 10 emits at an adjustable wavelength which lies in a wavelength range of 1580 to 1600 nm whilst the laser 20 is fixedly set at a wavelength of 1602 nm. In this way, an adjustable terahertz radiation from 0.23 to 2.6 THz can be produced by means of a linear element.

The outlet opening of the first laser 10 is directed onto a non-transmitting mirror 11 which is disposed such that it directs the radiation of the first laser 10 onto an inlet surface of a downstream beam splitter 21. The outlet opening of the second laser 20 is directed onto a second inlet surface of the beam splitter 21.

In the present embodiment, a second beam splitter 51 which splits the beam S5 into the beams S5′ and S5″ is located downstream of the first beam splitter 21. In alternative embodiments, a plurality of lasers can be provided (see below). In the present embodiment, the outlet surface of the first beam splitter 21 is facing the inlet surface of the second beam splitter 51. An outlet surface of the second beam splitter 51 is facing an inlet surface of a first nonlinear optical element 50, for example, a DAST crystal. A further outlet surface of the second beam splitter 51 is facing a beam deflecting apparatus 52, 53. In the present embodiment, the beam deflecting apparatus 52, 53 is designed from two mirrors 52 and 53 but it can also be designed in a particularly easy to handle manner as an optical fibre 52′.

The outlet surface of the first nonlinear optical element 50 is located facing the inlet surface of a second nonlinear optical element 60. The second linear optical element 60 can also be formed from a suitably prepared DAST crystal. The space R located between the two nonlinear optical elements 50 and 60 is provided to optionally accommodate the object to be studied as a sample space region R.

Instead of passing some of the transmitter radiation S5″ as a reference to the nonlinear optical element 60, radiation can be generated locally to shift the terahertz radiation again into the infrared. Analogously, in the radio receiver this would be a local oscillator. However, a bolometer or another terahertz detector can also be used directly without the nonlinear optical element 60. The different wavelengths in the terahertz range would then perhaps not be distinguishable, but these may be since they are sensitively modulated at different frequencies.

The outlet surface of the second nonlinear optical element 60 is facing the radiation-sensitive surface of a suitable sensor 90. In the present embodiment, a commercially available photodiode having a suitable spectral sensitivity is used. In systems designed for pure research purposes, however, a bolometer cooled with liquid helium can also be provided at this point. The sensor 90 is intended to convert the incident radiation into an electrical signal which is then passed to the control unit 40 via an interface 49. A suitable signal amplification can be provided in this case.

The control unit 40 is connected to a data memory 70 as well as an input-output unit 80. The input-output unit 80 can be the usual combination of a computer screen with corresponding keyboard. Terahertz spectra of known substances are stored in the data memory 70. In other words, terahertz spectra of various substances are stored in the data memory 70, wherein these terahertz spectra were previously determined using a similar or comparable system by introducing known reference samples. A commercially available PC can be considered as control unit 40, which is provided with suitable interfaces and suitable software. The spectral data in the data memory 70 are then provided in one or a plurality of files which can be accessed by further software which is specific for spectral evaluations. For mass production however, a combination of a microcontroller module with a specially programmed ASIC can be considered.

During operation the lasers 10 and 20 emit laser radiation S1 and S2. This combination of radiation yields the beam S5. The beam S5 is split into the beams S5′ and S5″ by the beam splitter 51. The beam S5′ is directed onto the nonlinear element 50. In the nonlinear element 50 the nonlinear superposition of the laser radiation S1 and S2 produces a difference wavelength whose frequency lies in the terahertz range. This frequency is particularly well suited for the safe and reliable transillumination of very diverse substances. The terahertz radiation field T thus produced is located directly downstream of the first nonlinear optical element. In the second nonlinear element 60, e.g. a photomixer, the terahertz radiation T formed and modified by the object to be studied and the reference beam S5″ are superposed. In this way, further radiation S9 is produced. This is again radiation in the wavelength range of the near infrared which is in turn detected by the sensor 90. The read-out measured value of the sensor 90 is stored together with the wavelength settings of the two lasers 10 and 20 in a temporary memory (not shown) of the control unit 40.

The adjustable laser 10 is then detuned (i.e. adjusted) slightly in a predetermined manner with regard to its emitted wavelength. This is accomplished by a suitable temperature variation of the resonator in the laser. The terahertz radiation now obtained as a result exhibits a different frequency from the previously generated terahertz radiation. In this way, as described previously, the corresponding wavelength as well as the radiation detected by the sensor 90 are stored in the control unit 40 in the temporary memory. This step can be repeated as frequently as necessary. Absorption values are preferably measured at least at three different terahertz wavelengths.

In this way, the spectral measuring system according to the invention has recorded at least three reference points for the terahertz absorption spectrum of the substance to be studied. Since each substance has a characteristic terahertz spectrum, it is now possible for the control unit 40 to output an indication of the substance currently to be measured on the basis of the spectra with assigned substances stored in the data memory by comparing with the spectrum which has just been measured.

The evaluation of the measured values is best explained with reference to FIG. 2 together with the following table. FIG. 2 shows three terahertz spectra of different explosives A, B and C. These comprise absorption spectra wherein the frequency is plotted on the right and the absorption is plotted at the top in arbitrary units. It is clearly noticeable that the explosive A has a relative absorption maximum at about 1.1 THz whereas the explosive B has a relative absorption maximum at about 0.8 THz and the explosive C has an only weakly defined relative absorption maximum at about 1.6 THz.

The laser 10 is adjusted so that this, together with the laser 20 effects the emission of four different terahertz waves at frequencies t1, t2, t3 and t4 from the first nonlinear element in a predetermined sequence. The frequencies t1, t2, t3 and t4 are selected in such a manner that they contain spectral characteristics of special explosives. A relative absorption maximum is advantageously considered as a spectral characteristic.

If the substance to be studied is now scanned in the terahertz radiation field generated as described above at the four predetermined frequencies t1, t2, t3 and t4, four measured values are determined which represent four points in the absorption spectrum of the substance to be studied. These four points serve as reference points for the following evaluation. On the basis of the stored spectra which are deposited in the data memory 70 of the control unit 40 as a spectral library as it were, the control unit 40 is now in a position to locate the stored spectrum having a maximum similarity to the measured spectrum based on the four reference points by means of one or a plurality of comparison operations. As the simplest method, the Euclidean distance between the measured spectrum and the stored spectra can be determined: that stored spectrum for which the Euclidean distance is minimal most probably pertains to that substance which is being measured instantaneously. If no substance was located in this method, a standardisation of all the spectra to be compared can be carried out as an additional step. A number of known methods exist whereby the most probable composition of the substance to be studied can be determined as well as a quality number which indicates the quality or statistical security of the substance information.

In this way, it can be determined rapidly and reliably whether and if so, which explosive is located in the space R. FIG. 3 shows a schematic diagram of the spectral measuring system in a second embodiment according to the invention. The same reference numerals as in FIG. 1 mean the same components with the same functionalities. The difference from the first embodiment is that in this case three lasers 10, 20 and 30 are provided which emit at respectively fixedly adjusted different wavelengths. The radiation of the laser 30 is coupled in via the beam splitter 31 so as to produce the beam S5. Unlike the first embodiment, in this case the reference radiation S5″ is additionally deflected via an optical fibre 52′ and directed onto the second nonlinear optical element 60. The triggering of the lasers 10, 20 and 30 is effected by a control unit 40′ which is modified with respect to the first embodiment.

The second embodiment according to the invention has the advantage that none of the lasers (10, 20, 30) needs to be detuned to achieve a spectral variation. The terahertz spectrum is rather scanned by respectively only two lasers emitting whilst the respectively third laser is switched off.

In this way, three different terahertz frequencies can be produced, shifted in time, by which means the absorption spectrum of a substance to be studied is scanned at precisely these three reference points. For example, the laser 10 can emit at 1995 nm, the laser 20 at 1600 nm and the laser 30 at 1610 nm. The control unit 40′ in each case triggers two lasers so that, depending on the combination, the terahertz frequencies 0.59 THz, 1.16 THz or 1.75 THz are generated. FIG. 4a shows an example for a time sequence of such a triggering.

FIG. 4a shows a schematic triggering diagram of the laser in the spectral measuring system in the second embodiment according to the invention. L10, L20 and L30 designate the switch-on times of the respective lasers 10, 20 and 30. For example, at time T1 only the lasers 10 and 20 are switched on so that the resulting terahertz radiation has a frequency of f1 THz. In the control unit 40 or the data memory 70 it is stored which combination of two lasers results in which terahertz radiation. By switching the lasers according to the triggering sequence shown, it is thus possible to determine the spectrum of the substance to be studied at three reference points. As described above, by comparison with the spectra stored in the memory 70′ the triggering unit calculates which substance is located in the space R with the highest probability.

If, according to an alternative modulation scheme according to FIG. 4b, the three lasers 10, 20, 30 are each modulated at a different pulse frequency, a different modulation frequency having the periods period 1, period 2 is obtained for the terahertz radiation for each wavelength f₁, f₂, f₃. Thus, the amplitudes can be measured at the receiver at three different modulation frequencies, period 1, 2, 3 and therefore the radiation can be determined at the regular terahertz wavelengths. In FIG. 4b this is shown for two of the three possible terahertz frequencies. The combination of the lasers 20, 30 cannot be seen in this diagram since their periods are greater than the time interval shown. Thus, quasi-continuous measurement can also be made.

In this context, the evaluation using the table below may explain the method in detail. The following table contains the absorption values of explosive A (“substance A”), explosive B (“substance B”) and explosive C (“substance C”) at the terahertz frequencies 0.6, 0.8, 1 and 1.1 THz. The table also contains a column (“measurement”) with a measured terahertz spectrum of an object to be studied. The respective column “Diff” contains alongside the respective substance spectra (“substance A”, “substance B” or “substance C”) the square of the difference between the currently measured absorption value and the stored respective absorption value of a substance at the corresponding frequency. Three values (6.24, 45.37 and 47.13) are entered in the lowermost lines. These are the square roots of the sum of the respective square of the distance per substance spectrum. In other words, these are the Euclidean distances from the currently measured spectrum to the respective substance spectrum. That stored substance spectrum which has a minimal Euclidean distance from the measured spectrum of the object to be studied indicates the substance contained in the object to be studied with the highest probability. It is clear that the quality of the prediction increases, the more substance spectra are stored in the data memory 40. With this method it is also possible to store terahertz spectra of substance mixture series in the data memory 40 so that even compositions and concentration of various substances can be detected by the measuring system according to the invention. It is clear that other mathematical methods can also be used for the evaluation of spectra. In particular, statistical methods can be considered here which additionally also output confidence intervals. Furthermore, it is possible by means of further mathematical methods to interpolate the reference points of the spectra. In this way, if a measuring system is to be assembled with a different number of laser diodes or different wavelengths are to be adjusted, it is possible to reuse the same terahertz spectra of known substances which have already been recorded once.

The teaching of measurement spectra can also be performed by neural networks.

| | | Sub- | | Sub- | | Sub- | |
|---|---|---|---|---|---|---|---|
| f/ | Measure- | stance | | stance | | stance | |
| THz | ment | A | Diff | B | Diff | C | Diff |
| 0.6 | 20 | 21 | 1 | 17 | 9 | 9 | 121 |
| 0.8 | 30 | 28 | 4 | 40 | 100 | 10 | 400 |
| 1 | 27 | 30 | 9 | 17 | 100 | 17 | 100 |
| 1.1 | 55 | 50 | 25 | 12 | 1849 | 15 | 1600 |
| | SQRT | | 6.24 | | 45.37 | | 47.13 |
| | (SUM) | | | | | | |

It is clear that more than three lasers can also be used. It is particularly advantageous if four to eight lasers having specified different wavelengths are used.

FIG. 5 shows a schematic diagram of the spectral measuring system in a third embodiment according to the invention. Similar reference numerals mean similar components as in the preceding figures. Three lasers 110, 120 and 130 triggered by a digital signal processor (DSP) 140 with data memory 170 are used in the third embodiment. A material sample M can optionally be introduced into the resulting terahertz radiation field T. The detector 190 converts the detected light intensity into an electrical signal which is evaluated by the DSP. The DSP outputs the result of the evaluation to the input-output unit 180.

FIG. 6 shows a schematic diagram of the spectral measuring system in a fourth embodiment according to the invention, wherein similar reference numerals mean similar components as in the preceding figures. The difference between this embodiment and the preceding ones is that the radiation emitted by four lasers 210, 220, 230 and 240 is in each case guided and combined by optical waveguides S201, S202, S203 and S204. This simplifies the assembly of the spectral measuring system since it is now no longer necessary to align the lasers individually. Rather, the optical waveguides can be suitably prefabricated so that during assembly of the measuring system, the ends of the optical waveguides only need to be placed in position.

FIG. 7 shows a schematic diagram of the spectral measuring system in a fifth embodiment according to the invention, wherein similar reference numerals mean similar components as in the preceding figures. The particular feature of the present embodiment is that in this case the measurements are made in a reflection arrangement. An SOA element 350′ emits terahertz radiation which is radiated by an imaging element into the sample space. The imaging element 355 can be a lens, for example, a Fresnel lens made of polyethylene. The terahertz radiation passes through the material M to be studied, is reflected by a reflecting surface R before finally being incident on a second imaging element 365 which can also be a Fresnel lens fabricated from polyethylene. The detector 390 then detects the radiation passing through the second imaging element and relays a corresponding signal to the DSP 340.

It is noted that the structure of the spectral measuring system according to the invention shown in FIG. 7, omitting a material M, is suitable for detecting temporally variable surface characteristics of the reflecting surface R. Thus, substance properties are made measurable. This is particularly advantageous when studying the activity of semiconductor chips.

It has been shown that the spectral measuring system according to the invention allows a rapid and reliable determination of substances or substance properties without the user requiring any specialist knowledge and that the invention can be implemented using inexpensive freely available components. This is achieved by delivering terahertz radiation among a plurality of predetermined wavelengths onto a material to be studied to interact therewith and evaluating the resulting radiation by a control unit with an associated data memory containing spectral measurement data.

FIG. 8 shows the sixth embodiment of the spectral measuring system according to the invention. In this case, only the elements absolutely necessary to explain the invention are shown. It is clear that further elements can be installed in a known manner such as, for example, variable delay sections, λ/2 or λ/4 plates, suitably selected filters and the like.

A radiation source 410 which can emit a plurality of radiation S401 of different wavelength, for example two wavelengths at λ1=1600 nm and λ2=1610 nm, is triggered by a control unit 440.

The outlet opening of the radiation source 410 is directed onto a non-transmitting mirror 411 which is disposed in such a manner that it directs the radiation of the radiation source 410 onto an inlet surface of a beam splitter 451 which splits the beam S405 into the beams S405′ and S405″. An outlet surface of the beam splitter 451 is facing an inlet surface of a first optical element 450, for example, a DAST crystal or a photoconducting antenna. A further outlet surface of the beam splitter 451 is facing a beam deflecting apparatus 452, 453. In the present embodiment the beam deflecting apparatus 452, 453 is designed from two mirrors 452 and 453 but it can also be designed in a manner particularly easy to handle as an optical fibre.

The outlet surface of the first optical element 450 is disposed facing the inlet surface of a second optical element 460. The second optical element 460 can also be formed from a suitably prepared BAST crystal or a photoconducting antenna, without applied external voltage. The space R located between the two optical elements 450 and 460 is provided to optionally accommodate the object to be studied as sample space region R.

The outlet surface of the second optical element 460 is facing the radiation-sensitive surface of a suitable sensor 490. In the present embodiment a commercially available photodiode having a suitable spectral sensitivity is used. In systems designed for pure research purposes, however, a bolometer cooled with liquid helium can also be provided at this point. The sensor 490 is intended to convert the incident radiation into an electrical signal which is then passed to the control unit 440 via an interface 449. A suitable signal amplification can be provided in this case.

The control unit 440 is connected to a data memory 470 as well as an input-output unit 480. The input-output unit 480 can be the usual combination of a computer screen with corresponding keyboard. Terahertz spectra of known substances are stored in the data memory 470. In other words, terahertz spectra of various substances are stored in the data memory 470, wherein these terahertz spectra were previously determined using a similar or comparable system by introducing known reference samples.

The evaluation of the measured values has already been explained comprehensively in the main application to which reference is expressly made here.

FIG. 9 shows the seventh embodiment of the spectral measuring system according to the invention. Similar reference numerals as in the figure shown previously mean similar components in this case.

A particular advantage with this embodiment is the direct generation of terahertz radiation by suitable electronic components such as, for example, large-area GaAs or ZnTe emitters 550. The radiation passed through the sample space or reflected by the sample is recorded by a suitable sensor circuit 560, S509, 590 and a form of electric measurement signals is fed to the control unit 540.

FIG. 10 shows a schematic diagram of a terahertz frequency comb in idealised view. In this case, a radiation power P is plotted versus a terahertz frequency. It is clear here that the terahertz radiation emitted by a suitable element has power maxima at different terahertz frequencies. In this way, a simultaneous spectrum of different terahertz frequencies is provided with a fixed distance among one another. It is clear that by means of suitable dimensions of the radiation source and a suitable triggering of the radiation source during operation, considerably more maxima can be provided than is shown here. The frequency comb as a whole can also be adjusted during operation in such a manner that the frequencies of the maxima are varied or the distances of the maxima are varied or both. If a radiation source with such a terahertz spectrum is used, triggering the radiation source for further variation of the wavelengths can be eliminated.

In other words, according to one aspect according to the invention, a spectral measuring system has been provided for determining substance properties using terahertz radiation, which comprises: one or more radiation sources of which at least one first radiation source is adjustable or configurable with regard to its wavelength, wherein the first radiation source emits first radiation having a predetermined first wavelength; and is characterised by a sensor which responds to further radiation which is based on the radiation of the at least one radiation source; a control unit which is connected to the at least one radiation source and the sensor; wherein the control unit is configured to trigger the at least one radiation source and to adjust the wavelength of the at least one adjustable radiation and to read out the sensor.

It has thus been shown that the spectral measuring system according to the invention can be built compactly and allows easy assembly without complex aligning actions.

### REFERENCE LIST

10 Laser (first radiation source)
11 First deflecting mirror
20 Laser (second radiation source)
21 Second deflecting mirror
30 Laser (third radiation source)
40 Control unit
41 Triggering interface
42 Triggering interface
49 Readout interface
50 First nonlinear optical element
51 Reference beam splitter
52, 53 Deflecting system
60 Second nonlinear optical element
70 Data memory
80 Input-output unit
90 Sensor
S1 Beam path of the first radiation source (laser 10)
S2 Beam path of the second radiation source (laser 20)
S5 Beam path of the combined beams
S5′ Sample beam path emerging from beam splitter
S5″ Reference beam path emerging from beam splitter
S9 Beam path directed to the sensor
410 Radiation source
411 Deflecting mirror
440, 540 Control unit
441, 541 Triggering interface
449, 549 Readout interface
450, 550 First optical element
451 Reference beam splitter
452, 453 Deflecting system
460, 560 Second optical element
470, 570 Data memory
480, 580 Input-output unit
490, 590 Sensor
S401 Beam path of the first radiation source 410
S405 Beam path of the reflected beams
S405′ Sample beam path emerging from beam splitter
S405″ Reference beam path emerging from beam splitter
S409 Beam path directed to the sensor
R Sample space region in which a sample to be studied can be located
T Radiation field acting on the sample

1-53. (canceled)

54. A spectral measuring system for determining substance properties using terahertz radiation, comprising:
more than two radiation sources which emit radiation at specified wavelengths which differ from one another;
a first optical element which, upon impingement of the radiation from the radiation sources, is configured to emit a terahertz radiation field in a sample space region in which an object to be studied comprising at least one substance is located;
a second optical element which is disposed in such a manner that it absorbs at least a part of the terahertz radiation modified by the object to be studied as well as radiation from the radiation sources deflected by means of a deflecting system, and is configured to emit further radiation based on the modified terahertz radiation and the radiation from the radiation sources;
a sensor which responds to the further radiation;
a control unit which is connected to the more than two radiation sources and the sensor, wherein the control unit is configured to trigger the more than two radiation sources and to read out the sensor;
wherein the control unit is configured to determine a terahertz spectrum of the object to be studied by triggering the more than two radiation sources as well as reading out the sensor, whereby the control unit makes the terahertz radiation based on an optional combination of two sets of radiation in each case of the radiation from the more than two radiation sources, wherein the beam paths of the more than two radiation sources are arranged in such a manner that they are directed onto the first optical element so that in succession a plurality of different terahertz waves is generated as a function of different radiation sources switched on simultaneously in twos according to predetermined switching frequencies which switch the radiation sources, wherein each of the optional combinations of respectively two of the switched-on radiation sources is a basis for the terahertz radiation.

55. The measuring system according to claim 54, wherein the radiation sources are configured as lasers and the first and second optical elements are configured as nonlinear optical elements.

56. The measuring system according to claim 55, wherein the radiation sources are configured as diode lasers.

57. The measuring system according to claim 54, wherein at least one of the radiation sources is sinusoidally or rectangularly modulated.

58. The measuring system according to claim 54, wherein each radiation source can be switched at a different frequency so that the resulting terahertz waves can be modulated or demodulated at different frequencies.

59. The measuring system according to claim 54, wherein the radiation from the radiation sources can be coupled onto optical fibres.

60. The measuring system according to claim 59, wherein the radiation from the radiation sources can be coupled onto individual optical fibres.

61. The measuring system according to claim 54, wherein the control unit is connected to an input-output unit as well as to a data memory in which at least one terahertz spectrum of a known substance is stored.

62. The measuring system according to claim 61, wherein the control unit is configured to compare the terahertz spectrum of the object to be studied with the at least one stored terahertz spectrum of the known substance and to output the result of the comparison to the input-output unit.

63. The measuring system according to claim 54, wherein the first optical element, the second optical element and the sample space region are disposed in such a manner with respect to one another that the terahertz radiation field that passes through the sample space region is absorbed by the second optical element.

64. The measuring system according to claim 54, wherein the first optical element, the second optical element and the sample space region are disposed in such a manner with respect to one another that the terahertz radiation field that is reflected at the sample space region is absorbed by the second nonlinear optical element.

65. The measuring system according to claim 54, wherein the deflecting system is achieved by a plurality of mirrors.

66. The measuring system according to claim 54, wherein the deflecting system is achieved by optical fibres.

67. The measuring system according to claim 54, wherein the radiation sources are integrated with a radiation amplifier on a semiconductor chip.

68. The measuring system according to claim 54, wherein the phase matching in the first optical element is improved by different phase angles of the incident radiation.

69. The measuring system according to claim 60, wherein the outlet end of the fibre can be arranged in such a manner in relation to the first optical element and the second optical element that the radiation emerging from the fibre can be partially incident on the first optical element and partially on the second optical element.

70. The measuring system according to claim 54, wherein imaging optical elements are provided.

71. The measuring system according to claim 70, wherein lenses fabricated from polyethylene function as imaging optical elements.

72. The measuring system according to claim 71, wherein the lenses are designed as Fresnel lenses.

73. The measuring system according to claim 54, wherein at least one of the optical elements is designed as a nonlinear optical element which consists of DAST (dimethyl amino 4-N-methylstilbazolium tosylate), KDP, ADP. lithium niobate, Ba2NaNb5O15, quartz, GaAs, GaP, BaTiO3, ZnO or CdS.

74. The measuring system according to claim 54, wherein the control unit is designed as an ASIC.

75. The measuring system according to claim 54, wherein the control unit is designed as a DSP.

76. The measuring system according to claim 54, wherein the control unit is designed as an embedded system.

77. The measuring system according to claim 54, wherein the data memory can be configured by an external source.

78. The measuring system according to claim 54, wherein the data memory is configured by means of a network connection, an internet connection, a telecommunication connection or an inductive connection.

79. The measuring system according to claim 54, wherein the input-output unit can comprise a screen, a mouse, a keypad, a disk drive, a CD or DVD drive, a magnetic tape drive, a hard disk, a network connection, an alarm signal generator, a telecommunications connection.

80. The measuring system according to 54, wherein the terahertz radiation field is radiation in the terahertz range from 0.1 terahertz to 100 terahertz.

81. The measuring system according to claim 54, wherein the radiation source is configured as a laser and at least one of the first and second optical element is configured as a nonlinear optical element or as a photoconducting antenna and/or photoconducting detector.

82. The measuring system according to claim 54, wherein at least one of the elements is configured as a photoconducting antenna.
